(19) United States
(12) Patent Application Publication
(10) Pub. No.: US 2019/0234696 A1
(43) Pub. Date: Aug. 1, 2019

(54) ELECTRONIC COMPONENT COOLER AND METHOD OF MANUFACTURING THE SAME

(71) Applicant: Hanon Systems, Daejeon (KR)

(72) Inventors: Wi Sam JO, Daejeon (KR); Hong-Young LIM, Daejeon (KR)

(21) Appl. No.: 16/265,468

(22) Filed: Feb. 1, 2019

(30) Foreign Application Priority Data
Feb. 1, 2018 (KR) 10-2018-0012706

(51) Int. Cl. F28F 9/02; H05K 7/20

(52) U.S. Cl. CPC F28F 9/0221; F28F 2009/0297; F28F 2230/00; H05K 7/2089

(57) ABSTRACT

Provided are an electronic component cooler configured in the form of a plate-type heat exchanger to smoothly ensure a gasket accommodation space and to have excellent manufacturing properties, and a method of manufacturing the electronic component cooler. In more detail, the electronic component cooler and the method of manufacturing the same enhance a design of a gasket accommodation space to stably accommodate a gasket and easily manufacture the electronic component cooler under a design limitation of an interval between tubes, which is limited to the thickness of a device. In addition, the electronic component cooler and the method of manufacturing the same smoothly accommodate the gasket to stably maintain sealing to effectively prevent a coolant from leaking.

### CROSS-REFERENCE TO RELATED APPLICATIONS

This application claims priority under 35 U.S.C. § 119 to Korean Patent Application No. 10-2018-0012706, filed on Feb. 1, 2018, in the Korean Intellectual Property Office, the disclosure of which is incorporated herein by reference in its entirety.

### TECHNICAL FIELD

The following disclosure relates to an electronic component cooler and a method of manufacturing the same, and more particularly, to an electronic component cooler having an enhanced structure for maintaining sealing and enhancing assembling properties in an electronic component cooler used in an eco-friendly vehicle such as an electric vehicle or a hybrid vehicle, and a method of manufacturing the same.

### BACKGROUND

Traditionally, a vehicle has used an engine driven via combustion of fossil fuel as a power source, but recently, research has been actively and rapidly conducted on an eco-friendly vehicle, e.g., a hybrid vehicle using both a motor and an engine driven by electricity or an electric vehicle using only a motor due to a problem of environmental pollution or fossil fuel depletion.

In an eco-friendly vehicle, a motor is rotated using electricity supplied from a storage battery as a power source to drive the vehicle, and in this case, an inverter for converting the electricity supplied to the motor from the power source into alternating current (AC) from direct current (DC) is installed in the vehicle. As such, the inverter includes a plurality of electronic devices for such power conversion, and in this regard, along with an increase in demand of an eco-friendly vehicle that requires high output, a design has been continuously enhanced and changed to acquire high of an output as possible. During this procedure, as the number of devices included in the inverter is increased, heat at a considerable level is generated while the inverter is operated. Accordingly, currently, a cooler for absorbing heat generated from a device and cooling the device while a coolant circulates in an inverter including a plurality of devices has been configured to be integrated into the inverter. To refer to as such a device, the eventual purpose of the device is conversion of power, and thus, the entire device is referred to as an inverter, but a cooler part for circulating a coolant is separately referred to as an inverter cooler. Japanese Patent Laid-Open Publication No. 2012-212776 (“Power Conversion Device”, Nov. 1, 2012, hereinafter, Related Art Document 1) discloses an example of the configuration of the inverter cooler. The inverter cooler disclosed in Related Art Document 1 is configured in such a way that a plurality of coolant tubes extending in one direction are stacked, a pair of tanks are connected at opposite ends of the stacked tubes, and a plurality of devices are disposed on the tubes. A coolant is introduced into the tank at one side, flows through the tubes, is collected in the tank at the other side, and then, is discharged, and during this procedure, heat generated from the device on the tube is absorbed into the coolant to cool the device.

An eco-friendly vehicle includes various electronic components as well as an inverter, and as described above, includes various coolers for cooling an electronic component as well as an inverter cooler for cooling an inverter. The electronic component cooler is not limited to a tube-tank type heat exchanger like in Relate Art Document 1, and may be configured in the form of a plate-type heat exchanger. The plate-type heat exchanger refers to a heat exchanger formed by stacking plates with unevenness and through holes formed therein. However, there is a limit in manufacturing an electronic component cooler in the form of a plate-type heat exchanger as follows. As described above, the electronic component cooler is configured to cool a device using a coolant, there is a risk in that the device is drastically damaged when sealing of the electronic component cooler is not maintained and a coolant leaks. Accordingly, sealing maintenance is a very important factor to be considered to design and manufacture the electronic component cooler. With regard to a design the electronic component cooler, to maximize device cooling efficiency, both opposite upper and lower surfaces of a device need to be in close contact with a tube in which a coolant circulates, and thus, there is a limit in that an interval between tubes is limited to the thickness of the device. However, when an electronic component cooler is manufactured in the form of a plate-type heat exchanger, a volume of a connection portion between plates is limited along with a reduction in an interval between tubes, and accordingly, it is difficult to install a gasket for sealing maintenance in the connection portion. Conventionally, to overcome this problem, a method of inserting a device and then compressing the device, and the like have been considered, but there is a problem in that a shape of a device is distorted, or a device is damaged during a compression procedure, and thus, it is also difficult to overcome the problem.

### RELATED ART DOCUMENT

### Patent Document

1. Japanese Patent Laid-Open Publication No. 2012-212776 (“Power Conversion Device”, Nov. 1, 2012).

### SUMMARY

An embodiment of the present disclosure is directed to providing an electronic component cooler configured in the form of a plate-type heat exchanger to smoothly ensure a gasket accommodation space and to have excellent manufacturing properties, and a method of manufacturing the electronic component cooler. In more detail, the object of the present invention is to enhance a design of a gasket accommodation space to stably accommodate a gasket and to easily manufacture the electronic component cooler under a design limitation of an interval between tubes, which is limited to the thickness of a device. In addition, the object of the present invention is to smoothly accommodate the gasket to stably maintain sealing to effectively prevent a coolant from leaking.

In one general aspect, an electronic component cooler 100 includes plurality of tubes 120 that extend in a length direction, have upper and lower surfaces, and circulate a coolant therein, and a pair of tanks 110 configured at opposite ends of the plurality of tubes 120 stacked in a height direction and configured to circulate a coolant in the tubes 120, the electronic component cooler 100 being configured by interposing a plurality of power conversion devices 200 between the tubes 120 to cool the device 200, wherein an upper surface through hole 121 and a lower surface through hole 122 are formed at opposite ends of upper and lower surfaces of the tube 120, and the tank 110 includes plurality of tank unit structures 115 that are coupled to the opposite ends of the tube 120 and are stacked in a height direction, wherein the tank unit structure 115 includes a first member 111 configured in such a way that a first through hole 111a is formed through the center of the first member 111, and a first accommodation groove 111b is formed to be recessed downward from an upper surface of the first member 111 to surround the first through hole 111a, the first member 111 having a lower surface coupled to the upper surface of the tube 120 to connect the first through hole 111a and the upper surface through hole 121 with each other, and a second member 112 configured in such a way that a second through hole 112a is formed through the center of the second member 112, and a second accommodation groove 112b is formed to be recessed upward from a lower surface of the second member 112 to surround the second through hole 112a, the second member 112 having an upper surface coupled to the lower surface of the tube 120 to connect the second through hole 112a and the lower surface through hole 122 with each other, and wherein, in the pair of tank unit structures 115 that are stacked, a gasket 130 is accommodated and disposed in a space formed by coupling the second accommodation groove 112b of a lower surface of the tank unit structure 115 at an upper side and the first accommodation groove 111b of an upper surface of a tank unit structure 115 at a lower side.

The electronic component cooler may further include an upper surface cover 113 for sealing the upper surface through hole 121 of the tube 120 at the upper most end, and a lower surface cover 114 for sealing the lower surface through hole 122 of the tube 120 at the lowermost end.

In the tank unit structure 115, the first member 111 and the second member 112 may be formed in the form of a block, and a first tube accommodation groove 111c may be formed to insert the tube 120 into a lower portion of the first member 111, or a second tube accommodation groove 112c may be formed to insert the tube 120 into an upper portion of the second member 112.

In the tank unit structure 115, the first tube accommodation groove 111c with a height corresponding to a height of the tube 120 may be formed only on the first member 111, the second tube accommodation groove 112c with a height corresponding to a height of the tube 120 may be formed only on the second member 112, or the first tube accommodation groove 111c and second tube accommodation groove 112c may be formed on the first member 111 and the second member 112, respectively, and the sum of a height of the first tube accommodation groove 111c and a height of the second tube accommodation groove 112c may correspond to a height of the tube 120.

In the tank unit structure 115,a first coupling hole 111d may be formed to penetrate the first member 111 at width-direction opposite ends of the first member 111, and a second coupling hole 112d may be formed to penetrate the second member 112 at width-direction opposite ends of the second member 112, in an assembly formed by stacking the plurality of tank unit structures 115, a screw rod 140 may be inserted into and may penetrate the first coupling holes 111d and the second coupling holes 112d that are connected with each other, and screws 145 may be coupled to height-direction opposite ends of the screw rod 140 to compress the plurality of tank unit structures 115 in a height direction.

In the tank unit structure 115, the first member 111 and the second member 112 may be formed in the form of a plate, and the first accommodation groove 111b and the second accommodation groove 112b may be formed by bending the first member 111 and the second member 112, respectively, via a pressing process.

In the tank unit structure 115, the first member 111 and the second member 112 may be configured in symmetrical shapes in an up and down direction.

The electronic component cooler 100 may further include a case 150 to which an assembly formed by stacking the plurality of tank unit structures 115 may be inserted and accommodated, wherein the assembly formed by stacking the plurality of tank unit structures 115 may be inserted into the case 150 to compress the plurality of tank unit structures 115 in a height direction.

In another general aspect, an electronic component cooler includes at least two unit tubes including a tube 120 that extends in a first direction and in which through holes 121 and 122 are formed in a direction that crosses the first direction, and first and second members 111 and 112 that are formed on one surface and the other surface of the tube 120 and in which a through hole 111a connected to the through holes 121 and 122 of the tube 120 is formed, and a gasket 130 disposed between the first and second members 111 and 112 and sealing therebetween.

The first and second members 111 and 112 may include a first accommodation groove 111b in which the gasket 130 is to be installed, and may be manufactured via a pressing process.

In another general aspect, a method of manufacturing the electronic component cooler as described above includes a tube manufacturing operation of coupling a lower surface of the first member 111 to the upper surface of the tube 120 to connect the first through hole 111a and the upper surface through hole 121 with each other, and coupling an upper surface of the second member 112 to the lower surface of the tube 120 to connect the second through hole 112a and the lower surface through hole 122 with each other, a device and gasket arrangement operation of disposing one unit tube, disposing the device 200 on an upper surface of the unit tube, and disposing the gasket 130 on the first accommodation groove 111b exposed through upper surfaces at opposite ends of the unit tube, when an assembly of the first member 111, the second member 112, and the tube 120, which are manufactured by the tube manufacturing operation, is the unit tube, a tube stack operation of disposing another unit tube on an upper surface of unit tube, on which the device 200 and the gasket 130 are disposed, and accommodating the gasket 130 in a space formed via coupling between the second accommodation groove 112b and the first accommodation groove 111b, which are exposed through lower surfaces at opposite ends of the another unit tube, and alternately and repeatedly performing the device and gasket arrangement operation and the tube stack operation.

### BRIEF DESCRIPTION OF THE DRAWINGS

FIG. 1 is a perspective view of an electronic component cooler according to the first embodiment of the present invention.

FIG. 2 is an exploded perspective view of the electronic component cooler according to a first embodiment of the present invention.

FIGS. 3 to 6 are cross-sectional views of the electronic component cooler according to the first embodiment of the present invention.

FIG. 7 is a perspective view of an electronic component cooler according to a second embodiment of the present invention.

FIG. 8 is an exploded perspective view of the electronic component cooler according to the second embodiment of the present invention.

FIGS. 9 and 10 are cross-sectional views of the electronic component cooler according to the second embodiment of the present invention.

### DETAILED DESCRIPTION OF EMBODIMENTS

Hereinafter, an electronic component cooler configured above and a method of manufacturing the same will be described in detail by explaining exemplary embodiments of the invention with reference to the attached drawings.

An electronic component cooler 100 according to the present invention may basically include a plurality of tubes 120 that extends in a length direction, has upper and lower surfaces, and circulates a coolant therein, and a pair of tanks 110 configured at opposite ends of the plurality of tubes 120 stacked in a height direction and configured to circulate a coolant in the tubes 120, and a plurality of power conversion devices 200 may be interposed between the tubes 120. That is, when a coolant is introduced into the tank 110 at one side, the coolant introduced into the tank 110 at one side may be distributed and introduced into the plurality of tubes 120, and the coolant may absorb heat generated from the device 200 that contacts the tube 120 while passing through the tube 120. The coolant that absorbs heat may be discharged from the plurality of tubes 120 and may be collected in the tank 110 at the other side, and the coolant collected in the tank 110 at the other side may be discharged to the outside. In this case, in the electronic component cooler 100 according to the present invention, an upper surface through hole 121 and a lower surface through hole 122 may be formed at opposite ends of upper and lower surfaces of the tube 120, and the tank 110 may include a plurality of tank unit structures 115 that are coupled to the opposite ends of the tube 120 and are stacked in a height direction.

As described above, a device is disposed between tubes, and in this regard, it would be obvious that heat is effectively transferred when upper and lower surfaces of the device need to correctly contact a plate surface of the tube. However, in the case of a conventional tube-tank type electronic component cooler, a tank unit is generally configured as an integrated component, and thus, it is not possible to change a shape in a thickness direction. In addition, in the case of the conventional tube-tank type electronic component cooler, the device is inserted between tubes after the electronic component cooler is completely manufactured, and as described above, an interval between tubes is almost the same as the height of the device to achieve correct contact between the device and the tube, and thus, there is a high risk of damaging the device or the tube during the device and tube insertion process.

However, according to the present invention, the tank 110 is configured in the form of a stack structure of the plurality of tank unit structures 115, and thus, it may be possible to change a shape in a height direction. That is, when the device 200 is disposed between the tubes 120 and then the tank unit structures 115 are compressed in the height direction, contact between the device and the tube may become excellent along with a reduction in the interval between the tubes 120, and as a result, heat may be smoothly transferred and cooling performance of a device may be maximized.

As such, when the tank 110 is configured in the form of a stack structure of unit structures, it may be very important to maintain sealing to prevent a coolant from leaking. In the case of a conventional tank that is integrally configured, it is relatively easy to maintain sealing, but in the case of an assembly configured in the form of a stack structure of unit structures as such, it may be relatively difficult to stably maintain sealing. In addition, in order to insert a gasket between unit structures for sealing maintenance, the interval between the tubes is also significantly small at a height level of the device, and thus, it is difficult to form a space for accommodation of the gasket. However, according to the present invention, a gasket accommodation space may be formed according to a shape of the tank unit structure 115 while the tank unit structures 115 are stacked on each other, and the problem in terms of sealing maintenance may be overcome.

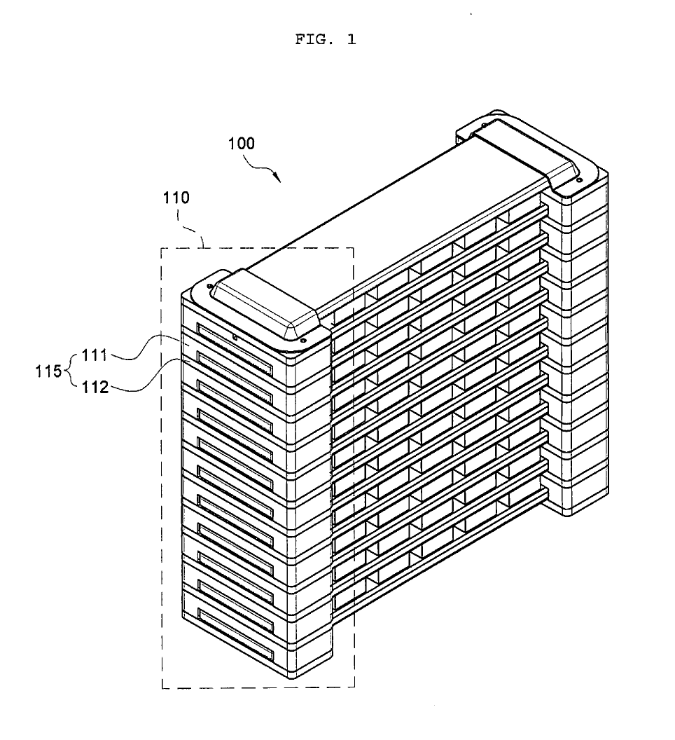

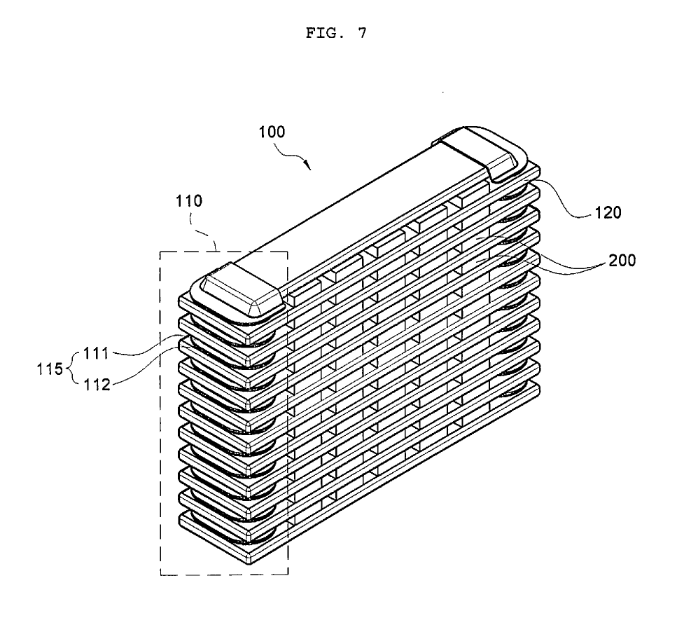

FIGS. 1 to 6 show the electronic component cooler 100 according to a first embodiment, and FIGS. 7 to 10 show the electronic component cooler 100 according to a second embodiment. In both the first and second embodiments, the tank unit structure 115 may include a first member 111 and a second member 112 that are coupled to opposite ends of the tube 120. First, the configuration of the electronic component cooler 100 will be described based on the first embodiment of the present invention in more detail, and the second embodiment will be described in terms of a difference from the first embodiment.

Electronic Component Cooler according to First Embodiment of Present Invention

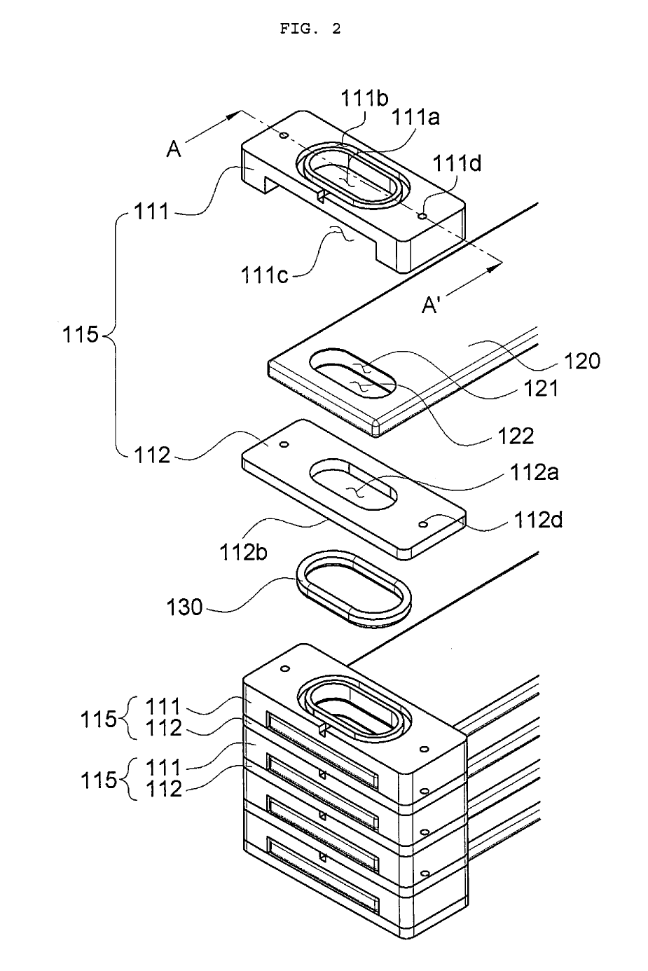

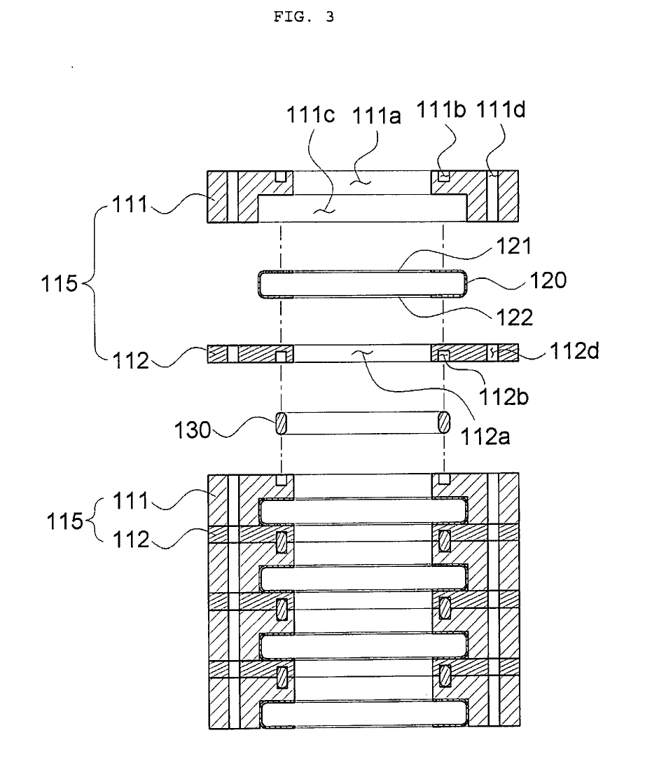

FIG. 1 is a perspective view of an electronic component cooler according to the first embodiment of the present invention. FIG. 2 is an exploded perspective view of the electronic component cooler according to the first embodiment of the present invention. FIGS. 3 to 6 are cross-sectional views of the electronic component cooler according to the first embodiment of the present invention. The first embodiment will be described in detail with reference to the overall drawings of FIGS. 1 to 6.

As described above, in the electronic component cooler 100 according to the present invention, the tank unit structure 115 may include the first member 111 and the second member 112.

As shown in FIG. 1, etc., the first member 111 may be configured in such a way that a first through hole 111a is formed through the center of the first member 111, and a lower surface of the first member 111 may be coupled to an upper surface of the tube 120 to connect the first through hole 111a and the upper surface through hole 121 to each other. Accordingly, a coolant circulating in the tube 120 may circulate in the first through hole 111a through the upper surface through hole 121.

As shown in FIG. 1, etc., the second member 112 may also be configured in such a way that a second through hole 112a is formed through the center, and an upper surface of the second member 112 is coupled to a lower surface of the tube 120 to connect the second through hole 112a and the lower surface through hole 122 to each other, similarly to the first member 111. Accordingly, a coolant circulating in the tube 120 may circulate in the second through hole 112a through the lower surface through hole 122.

The first member 111 may be coupled to the upper surface of the tube 120, and the second member 112 may be coupled to the lower surface of the tube 120. Coupling between the first member 111 and the tube 120 and coupling between the second member 112 and the tube 120 may be achieved via brazing coupling. When an assembly of the first member 111, the second member 112, and the tube 120 is a unit tube, one unit tube may include one tube 120, a pair of first members 111, and a pair of second members 112 (which are configured at opposite ends of the tube, respectively). With regard to flow of a coolant in the unit tube, when the coolant is introduced through the tank unit structure 115 at one side (which is configured by coupling the first member 111 and the second member 112 to each other), the coolant may flow into the tube 120 through the upper surface through hole 121 and the lower surface through hole 122 at one side, connected to the tank unit structure 115. The coolant flowing into the tube 120 may be discharged to the tank unit structure 115 at the other side, connected to the upper surface through hole 121 and the lower surface through hole 122 at the other side.

The plurality of unit tubes are stacked to form the electronic component cooler 100, and in this case, the unit tube configured as described above is configured via brazing coupling between units, and thus, there is a relatively low risk of coolant leaking at a coupling portion of a tube-tank unit structure. However, when the tank unit structures 115 are stacked, sealing between the tank unit structures 115 may not be relatively and stably maintained, and thus, there is a risk of coolant leaking. According to the present invention, a space for accommodation of the gasket may be formed at the coupling portion between the tank unit structures 115 to overcome the problem.

As shown in FIG. 1, etc., a first accommodation groove 111b may be formed on an upper surface of the first member 111 to be recessed downward from the upper surface to surround the first through hole 111a, and a second accommodation groove 112b may be formed on a lower surface of the second member 112 so as to be recessed upward from the lower surface to surround the second through hole 112a. In this case, when the tank unit structures 115 are stacked, a lower surface of the tank unit structure 115 at an upper side and an upper surface of the tank unit structure 115 at a lower side may contact each other. With regard to a pair of the tank unit structures 115 that are stacked as such, a gasket 130 may be accommodated and disposed in a space formed via coupling between the second accommodation groove 112b formed on the lower surface of the tank unit structure 115 at the upper side and the first accommodation groove 111b formed on the upper surface of the tank unit structure 115 at the lower side. As such, a gasket accommodation space may be formed at a coupling portion between the tank unit structures 115, and thus, sealing between the tank unit structures 115 may be stably maintained, thereby preventing a risk of coolant leaking.

When the gasket 130 is not present, surface roughness of surfaces (i.e., upper and lower surfaces) of the tank unit structures 115, which make contact with each other, need to be very high in order to stably maintain sealing between the tank unit structures 115. However, to this end, members of the tank unit structure 115 need to be manufactured, and then, a separate process for enhancing surface roughness needs to be performed, and during this procedure, the number of processes and manufacturing costs may be increased. However, according to the present invention, a gasket accommodation space may be formed at a coupling portion between the tank unit structures 115, and the gasket 130 may be inserted into the gasket accommodation space to maintain sealing, and thus, it may not be required to maintain surface roughness, thereby reducing the number of processes and manufacturing costs.

In the tank unit structure 115 according to a first embodiment shown in FIGS. 1 to 6, the first member 111 and the second member 112 may be formed in the form of a block. That is, it may be possible to easily manufacture the first member 111 and the second member 112 via only a simple process such as a process of perforating a raw material block to form a hole, or a process of forming a groove.

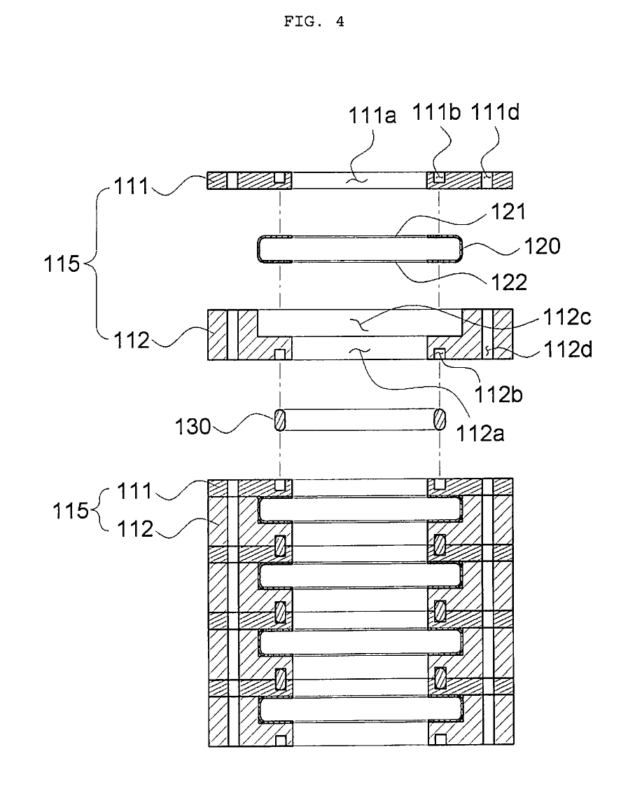

In the tank unit structure 115 according to the first embodiment, as shown in FIGS. 1 to 3, a first tube accommodation groove 111c may be formed to insert the tube 120 into a lower portion of the first member 111, or as shown in FIG. 4, a second tube accommodation groove 112c may be formed to insert the tube 120 into an upper portion of the second member 112. The first tube accommodation groove 111c or the second tube accommodation groove 112c may be formed, and thus, the tube 120 may be stably guided into a block type member to be easily disposed at an original position.

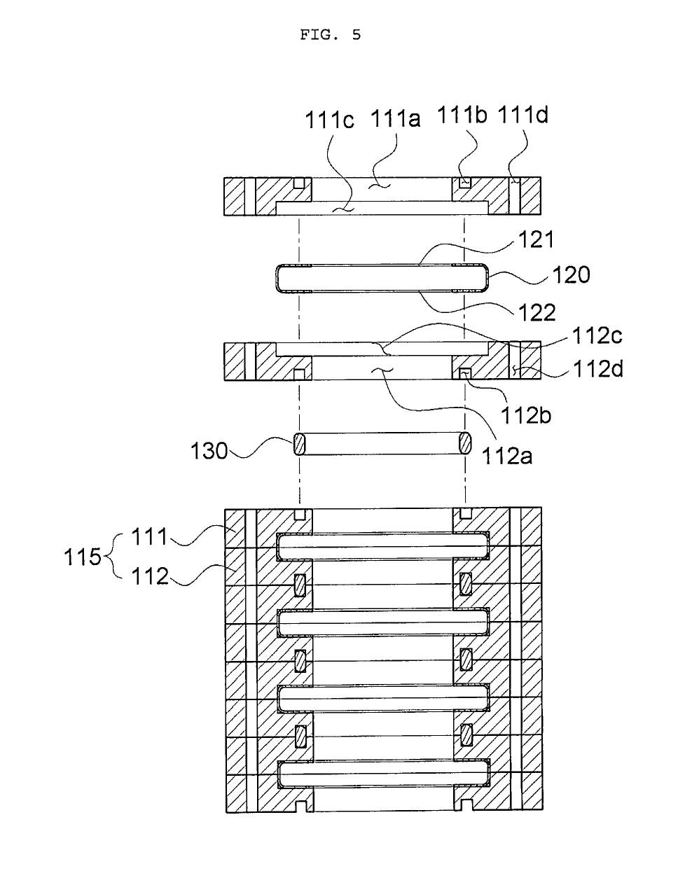

In this case, as shown in FIGS. 1 to 3, when the first tube accommodation groove 111c is formed only on the first member 111, the first tube accommodation groove 111c may have a height corresponding to the height of the tube 120. As shown in FIG. 4, when the second tube accommodation groove 112c is formed only on the second member 112, the second tube accommodation groove 112c may have a height corresponding to the height of the tube 120. As shown in FIG. 5, when both the first tube accommodation groove 111c and the second tube accommodation groove 112c are formed on the first member 111 and the second member 112, respectively, the sum of heights of the first tube accommodation groove 111c and the second tube accommodation groove 112c may correspond to the height of the tube 120.

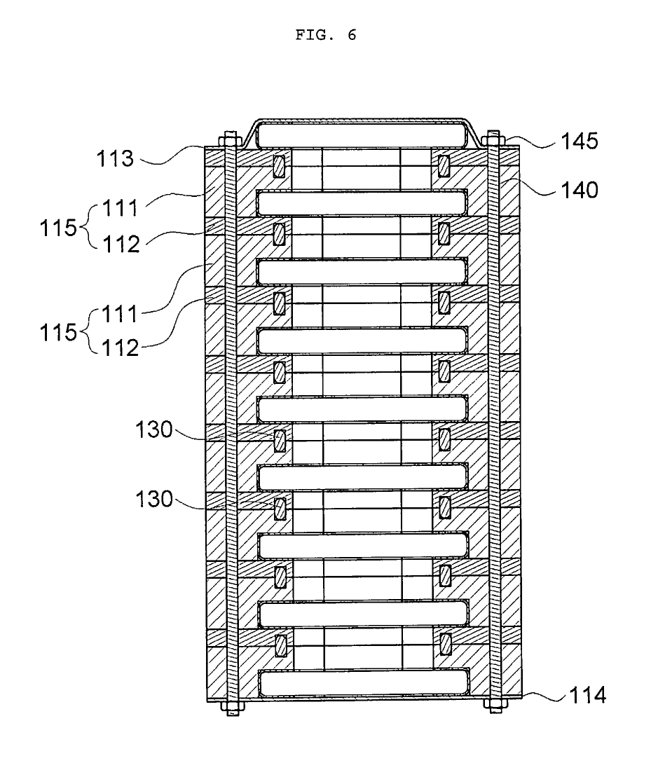

FIG. 6 is a cross-sectional view showing a state in which the unit tubes formed via coupling of the tube, the first member, and the second member as described above are stacked to completely form one electronic component cooler 100. As described above, the tank 110 may be formed by stacking the plurality of tank unit structures 115 formed by stacking the unit tubes. In this case, the upper surface through hole 121 of the tube 120 at the uppermost end and the lower surface through hole 122 of the tube 120 at the lowermost end may be in an open state because there is no other tank unit structures 115 above and below the tube 120. Accordingly, the electronic component cooler 100 may further include an upper surface cover 113 for sealing the upper surface through hole 121 of the tube 120 at the uppermost end and a lower surface cover 114 for sealing the lower surface through hole 122 of the tube 120 at the lowermost end. For convenience, FIG. 6 illustrates an example in which both the upper surface cover 113 and the lower surface cover 114 are formed, but needless to say, one of covers at one side and the other side may not be included or a through hole may be formed at any place of covers to be connected to the outside in order to allow a coolant to be introduced into the tank 110 or to discharge a coolant from the tank 110.

Like in the first embodiment, when the first member 111 and the second member 112 are configured in the form of a block, the tank unit structure 115 may be formed as follows. First, a first coupling hole 111d may be formed to penetrate the first member 111 at width-direction opposite ends of the first member 111, and a second coupling hole 112d may be formed to penetrate the second member 112 at width-direction opposite ends of the second member 112. With regard to an assembly formed by stacking the plurality of tank unit structures 115 including the first member 111 and the second member 112, as shown in FIG. 6, a screw rod 140 may be inserted to penetrate the first coupling holes 111d and the second coupling holes 112d that are connected with each other. In this state, when screws 145 are coupled to height-direction opposite ends of the screw rod 140 and are tightened, the plurality of tank unit structures 115 may be compressed in a height direction.

As described above, the devices 200 may be interposed between the tubes 120, and as a planar surface of the tube 120 and upper and lower surfaces of the device 200 completely and more closely surface-contact each other, heat may be smoothly transferred, thereby enhancing an effect of cooling a device. In this, according to the present disclosure, the assembly formed by stacking the plurality of tank unit structures 115 may be compressed in the height direction using the screw rod 140 and the screws 145 disposed at opposite ends thereof, and thus, an interval between the tubes 120 may also be further reduced after the assembly is completed. Accordingly, adherence between the planar surface of the tube 120 and the upper and lower surfaces of the device 200 may become excellent, that is, the device cooling effect may be effectively enhanced.

Electronic Component Cooler according to Second Embodiment of Present Invention

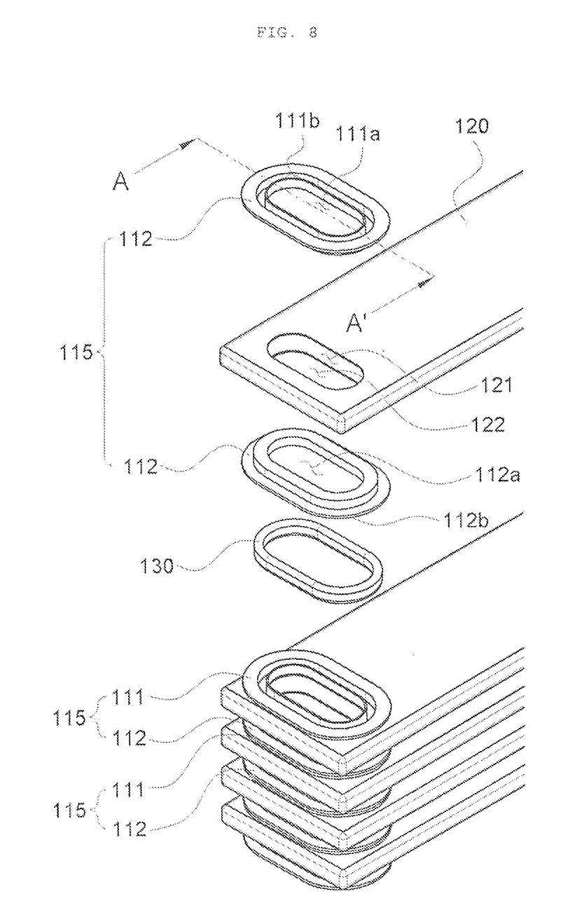

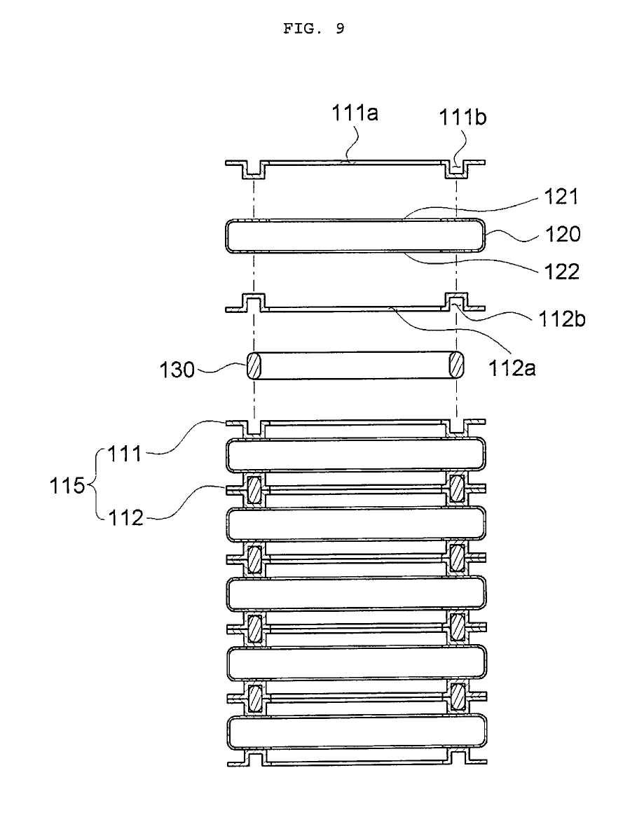

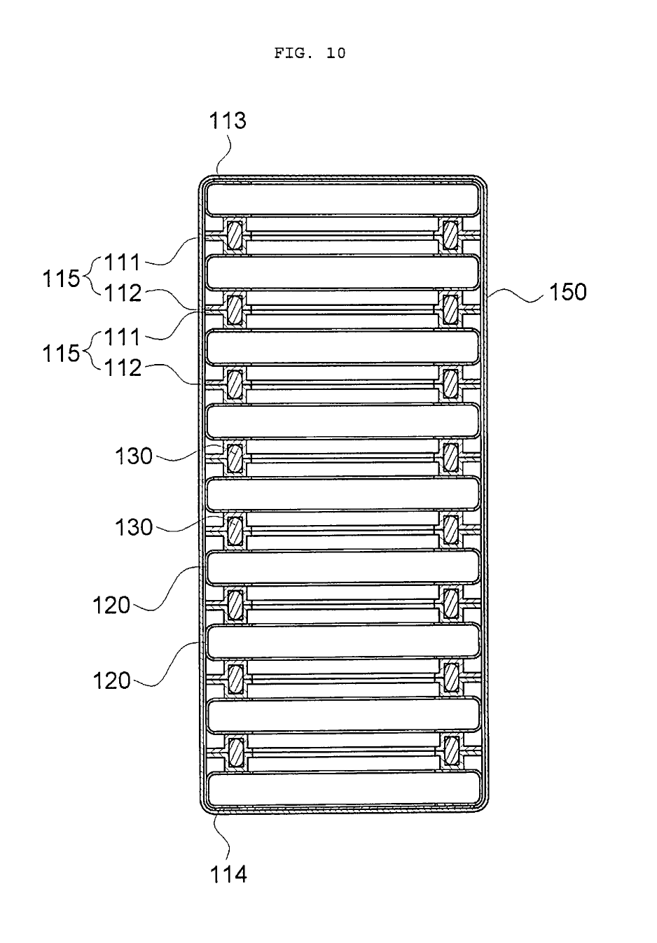

FIG. 7 is a perspective view of an electronic component cooler according to the second embodiment of the present invention. FIG. 8 is an exploded perspective view of the electronic component cooler according to the second embodiment of the present invention. FIGS. 9 and 10 are cross-sectional views of the electronic component cooler according to the second embodiment of the present invention. The second embodiment will be described in detail with reference to the overall drawings of FIGS. 7 to 10.

Like in the above first embodiment, according to the second embodiment, the first member 111 and the second member 112 may be coupled to configure the tank unit structure 115, the tube 120 at the uppermost end may include the upper surface cover 113 for sealing the upper surface through hole 121, and the tube 120 at the lowermost end may include the lower surface cover 114 for sealing the lower surface through hole 122. However, the second embodiment is different from the first embodiment in that the first member 111 and the second member 112 are formed in the form of a plate in the second embodiment, differently from the first embodiment in which the first member 111 and the second member 112 are manufactured by cutting a block. In this case, the first accommodation groove 111b and the second accommodation groove 112b may be formed by bending the first member 111 and the second member 112,respectively, via a pressing process.

Like in the second embodiment, when the first member 111 and the second member 112 are manufactured via a pressing process, the first member 111 and the second member 112 may be manufactured with a desired shape via only a process of pressing a plate. In detail, ideally, when edge cutting is also performed via pressing, it may be possible to manufacture a member via only single time pressing, single time pressing may be performed on a plate that is a parent member to form accommodation grooves, and then, the plate may be cut once to an appropriate size to completely manufacture a member. That is, the number of processes of manufacturing a member may be ideally reduced to about one to two, and thus, it may be advantageous to remarkably reduce the number of producing processes compared with the conventional case.

As such, flatness of a plate may be degraded, for example, the plate is dented during a pressing process of the plate, but according to the present invention, the gasket 130 is accommodated and disposed between accommodation grooves formed via pressing, and thus, stable sealing performance may be achieved irrespective of the flatness of members. Conventionally, it is difficult to accommodate a sealing member (gasket) between members, and thus, a process of enhancing member surface roughness to achieve excellent surface-contact between members to prevent leakage is required. However, as described above in the first embodiment, according to the present invention, it may be easy to dispose a gasket using a shape (an accommodation groove) of members, and accordingly, excellent sealing performance may be achieved without an excessive increase in surface roughness or flatness of members.

As such, when the first member 111 and the second member 112 are formed in the form of a plate, if the unit tube is manufactured via brazing coupling between the first member 111 and the second member 112 at opposite ends of the tube 120, the volume of the unit tube may not be largely increased compared with the tube 120, as intuitively seen from comparison between FIGS. 1 to 6 showing the first embodiment and FIGS. 7 to 10 showing the second embodiment. That is, compared with the first embodiment, the volume of the electronic component cooler 100 according to the second embodiment may be highly reduced.

According to the second embodiment, as shown in the drawings, the first member 111 and the second member 112 may be configured in symmetrical shapes in an up and down direction. In this case, when only one of the first member 111 and the second member 112 is inverted, the same shape as a target shape may be achieved, and thus, only one component may be simply manufactured in actual manufacture, thereby further reducing the number of processes and manufacturing costs.

According to the first embodiment, because the first member 111 and the second member 112 are configured in the form of a block, structural stability may be relatively high, and accordingly, compression may be performed in the height direction using the screw rod 140 and the screw 145. However, according to the second embodiment, because the first member 111 and the second member 112 are configured in the form of a plate, there is a risk in that members are dented or damaged when a screw coupling method is used. Accordingly, according to the second embodiment, as shown in FIG. 10, the electronic component cooler 100 may further include a case 150 for inserting and accommodating an assembly formed by stacking the plurality of tank unit structures 115, and the assembly formed by stacking the plurality of tank unit structures 115 may be inserted into the case 150 to compress the plurality of tank unit structures 115 in the height direction. The height of the case 150 is slightly smaller than the height of the assembly formed by stacking the plurality of tank unit structures 115, and thus, a process of compressing the assembly formed by stacking the plurality of tank unit structures 115 in a height direction may be easily performed during a press fitting and coupling procedure.

Method of Manufacturing Electronic Component Cooler according to Present Invention

As described above, in the electronic component cooler 100 according to the present invention, the tank 110 is not configured in an integration type, and instead, the electronic component cooler 100 may be manufactured in such a way that unit tubes formed by coupling the tank unit structure 115 and the tube 120 are stacked. Conventionally, a device needs to be inserted between tubes after an electronic component cooler is completely manufactured, and thus, many problems arise in that a device is damaged a device is separated from an original position and the like, but the electronic component cooler 100 according to the present invention may be manufactured by alternately repeating a unit structure stack process and a device arrangement process, and thus, the problems may be originally prevented. A method of manufacturing the electronic component cooler 100 according to the present invention may include a tube manufacturing operation, a device arrangement operation, a gasket arrangement operation, and a tube stack operation, and each operation will be described below in detail.

In the tube manufacturing operation, a lower surface of the first member 111 may be coupled to an upper surface of the tube 120 to connect the first through hole 111a and the upper surface through hole 121 with each other, and an upper surface of the second member 112 may be coupled to a lower surface of the tube 120 to connect the second through hole 112a and the lower surface through hole 122 with each other to manufacture a unit tube. There is no problem when the tube manufacturing operation is independently performed from a stack assembly operation, and thus, the tube manufacturing operation may be pre-performed in any degree.

In the device and gasket arrangement operation, one unit tube may be disposed, and the device 200 may be disposed on an upper surface of the unit tube. The gasket 130 may be disposed on the first accommodation groove 111b, which is exposed through the upper surface of the unit tube at opposite ends. There is no problem when any one of arrangement of the device 200 and arrangement of the gasket 130 is first performed.

Then, in the tube stack operation, another unit tube may be disposed on the upper surface of the unit tube, on which the device 200 is disposed. The unit tube is disposed as such, and thus, the gasket 130 may be accommodated in a space formed by coupling the second accommodation groove 112b and the first accommodation groove 111b, which are exposed through a lower surface of another unit tube at opposite ends.

As such, when unit tube arrangement, device and gasket arrangement, unit tube arrangement, device and gasket arrangement, and unit tube arrangement, and the like are alternately performed, the device 200 or the unit tube are not separately compressed, and accordingly, there is no risk of damaging the device 200 due to press fitting or the like. As such, the device and gasket arrangement operation and the tube stack operation are alternately and repeatedly performed, and thus, an assembly formed by stacking the plurality of tank unit structures 115 may be completely manufactured.

In addition, the method of manufacturing the electronic component cooler may further include a process of further coupling the upper surface cover 113 and the lower surface cover 114. This operation may be independently performed as a separate operation of manufacturing a tube for the uppermost end or the lowermost end, like the tube manufacturing operation of manufacturing a unit tube. That is, this operation may also be independently performed in any degree from a stack assembly process.

The method of manufacturing the electronic component cooler may further include a process of compressing the assembly formed by stacking the plurality of tank unit structures 115 in a height direction. When the electronic component cooler 100 is configured like in the first embodiment, this process may be embodied as a process of tightening the screw 145 at the screw rod 140, and when the electronic component cooler 100 is configured like in the second embodiment, this process may be embodied as a process of inserting the assembly into the case 150 via press fitting.

According to the present invention, a design of a gasket accommodation space may be enhanced while an electronic component cooler is configured in the form of a plate-type heat exchanger, and accordingly, a problem in that it is difficult to ensure the gasket accommodation space due to a design limitation of an interval between tubes, which is limited to the thickness of a device, may be overcome, and as a result, sealing for gasket accommodation space may be stably maintained while being configured in the form of the plate-type heat exchanger, thereby achieving an effect of effectively preventing a coolant from leaking.

According to the present invention, it may be easy to compress a stack structure of tubes in a height direction in which the tubes are stacked, due to an enhanced structure, and thus, an effect of stably maintaining sealing and preventing coolant leakage may be further enhanced. In addition, it is generally important to manage surface roughness of a component for fixing and compressing a gasket, and thus, a processing process for enhancing the surface roughness is required, and accordingly, there is a problem in that the number of processes and manufacturing costs are increased, but according to the present invention, it is easy to compress the stack structure in the height direction, as described above, and thus, it may not be required to excessively increase surface roughness. In addition, according to the present invention, members for forming a tank portion for connecting tubes with each other may be very easily manufactured via a pressing process. As such, the present invention may have an effect of remarkably lowering the number of processes and manufacturing costs.

In particular, according to the present invention, the electronic component cooler may be configured in the form of a plate-type heat exchanger, but not in the form of a conventional tube-tank type heat exchanger, and thus, a process of stacking plates and a process of disposing a device between plates may be simultaneously performed to manufacture the electronic component cooler. That is, a conventional process of inserting a device between tubes after the electronic component cooler is manufactured may be omitted, and thus, there is an effect of simplifying a process. Accordingly, according to the present invention, the unit structure stack process and the device arrangement process are alternately and repeatedly performed to manufacture the electronic component cooler, thereby achieving a significant effect of originally preventing conventional problems in that, for example, a device is damaged or is not disposed at an original position while the device is inserted between tubes and the like.

Accordingly, it will be obvious to those skilled in the art to which the present disclosure pertains that the present disclosure described above is not limited to the above-mentioned exemplary embodiments and the accompanying drawings, but may be variously substituted, modified, and altered without departing from the scope and spirit of the present disclosure.

1.-13. (canceled)

14. An electronic component cooler comprising a plurality of tubes that extend in a length direction, have upper and lower surfaces, and circulate a coolant therein, and a pair of tanks configured at opposite ends of the plurality of tubes stacked in a height direction and configured to circulate the coolant in the tubes, the electronic component cooler being configured by interposing a plurality of power conversion devices between the tubes to cool the device,
wherein an upper surface through hole and a lower surface through hole are formed at opposite ends of the upper and lower surfaces of the tube, and the tank includes plurality of tank unit structures that are coupled to the opposite ends of the tube and are stacked in the height direction.

15. The electronic component cooler of claim 14, wherein the tank unit structure includes a first member configured in such a way that a first through hole is formed through the center of the first member, and a first accommodation groove is formed to be recessed downward from an upper surface of the first member to surround the first through hole, the first member having a lower surface coupled to the upper surface of the tube to connect the first through hole and the upper surface through hole with each other; and
a second member configured in such a way that a second through hole is formed through the center of the second member, and a second accommodation groove is formed to be recessed upward from a lower surface of the second member to surround the second through hole the second member having an upper surface coupled to the lower surface of the tube to connect the second through hole and the lower surface through hole with each other.

16. The electronic component cooler of claim 15, wherein, in the pair of tank unit structures that are stacked, a gasket is accommodated and disposed in a space formed by coupling the second accommodation groove of a lower surface of a tank unit structure at an upper side and the first accommodation groove of an upper surface of a tank unit structure at a lower side.

17. The electronic component cooler of claim 16, further comprising an upper surface cover for sealing the upper surface through hole of the tube at the upper most end, and a lower surface cover for sealing the lower surface through hole of the tube at the lowermost end.

18. The electronic component cooler of claim 16, wherein, in the tank unit structure, the first member and the second member are formed in the form of a block, and a first tube accommodation groove is formed to insert the tube into a lower portion of the first member, or a second tube accommodation groove is formed to insert the tube into an upper portion of the second member.

19. The electronic component cooler of claim 18, wherein, in the tank unit structure,
the first tube accommodation groove with a height corresponding to a height of the tube is formed only on the first member,
the second tube accommodation groove with a height corresponding to the height of the tube is formed only on the second member, or
the first tube accommodation groove and second tube accommodation groove are formed on the first member and the second member, respectively, and the sum of a height of the first tube accommodation groove and a height of the second tube accommodation groove corresponds to the height of the tube.

20. The electronic component cooler of claim 18, wherein, in the tank unit structure,
a first coupling hole is formed to penetrate the first member at width-direction opposite ends of the first member, and a second coupling hole is formed to penetrate the second member at width-direction opposite ends of the second member;
in an assembly formed by stacking the plurality of tank unit structures, a screw rod is inserted into the first coupling holes and the second coupling holes d that are connected with each other; and
screws are coupled to height-direction opposite ends of the screw rod to compress the plurality of tank unit structures in the height direction.

21. The electronic component cooler of claim 16, wherein, in the tank unit structure,
the first member and the second member are formed in the form of a plate; and
the first accommodation groove and the second accommodation groove are formed by bending the first member and the second member, respectively, via a pressing process.

22. The electronic component cooler of claim 21, wherein, in the tank unit structure, the first member and the second member are configured in symmetrical shapes in an up and down direction.

23. The electronic component cooler of claim 21, further comprising a case to which an assembly formed by stacking the plurality of tank unit structures is inserted and accommodated,
wherein the assembly formed by stacking the plurality of tank unit structures is inserted into the case to compress the plurality of tank unit structures in the height direction.

24. A method of manufacturing the electronic component cooler of claim 14, the method comprising:
a tube manufacturing operation of coupling a lower surface of the first member to the upper surface of the tube to connect the first through hole and the upper surface through hole with each other, and coupling an upper surface of the second member to the lower surface of the tube to connect the second through hole and the lower surface through hole with each other;
a device and gasket arrangement operation of disposing one unit tube, disposing the device on an upper surface of the unit tube, and disposing the gasket on the first accommodation groove b exposed through upper surfaces at opposite ends of the unit tube, when an assembly of the first member, the second member, and the tube, which are manufactured by the tube manufacturing operation, is the unit tube;
a tube stack operation of disposing another unit tube on an upper surface of unit tube, on which the device and the gasket are disposed, and accommodating the gasket in a space formed via coupling between the second accommodation groove and the first accommodation groove b, which are exposed through lower surfaces at opposite ends of the another unit tube; and
alternately and repeatedly performing the device and gasket arrangement operation and the tube stack operation.

25. An electronic component cooler comprising:
at least two unit tubes including a tube that extends in a first direction and in which through holes and are formed in a direction that crosses the first direction, and first and second members and that are formed on one side surface and the other surface of the tube and in which a through hole a connected to the through holes and of the tube is formed, and
a gasket disposed between the first and second members and sealing therebetween.

26. The electronic component cooler of claim 25, wherein the first and second members and include a first accommodation groove b in which the gasket is to be installed, and is manufactured via a pressing process.
